(19) United States
(12) Patent Application Publication
(10) Pub. No.: US 2007/0040552 A1
(43) Pub. Date: Feb. 22, 2007

(54) Spin stand

(75) Inventor: Eiji Ishimoto, Hyogo (JP)

Correspondence Address: OHLANDT, GREELEY, RUGGIERO & PERLE, LLP, ONE LANDMARK SQUARE, 10TH FLOOR, STAMFORD, CT, 06901, US

(73) Assignee: AGILENT TECNOLOGIES, INC., PALO ALTO, CA (US)

(21) Appl. No.: 10/554,983

(22) PCT Filed: Jun. 23, 2004
(86) PCT No.: PCT/JP04/09251

§ 371 Date: Oct. 31, 2005

(30) Foreign Application Priority Data
Jun. 25, 2003 (JP) 2003-180496

(51) Int. Cl. G01R 33/00

(52) U.S. Cl. 324/261; 324/262

(57) ABSTRACT

A spin stand for testing a head or disk, comprising a base and a stage connected to the base through a rolling bearing. In the spin stand, the stage can be rapidly and stably fixed to the base. A fixing device is sucked to be connected to the base and the stage, and the stage is fixed to the base.

### FIELD OF THE INVENTION

The present invention pertains to a spin stand for testing heads or disks, and in particular, relates to a spin stand comprising a base and a stage that communicates with the base via an antifriction bearing.

### DISCUSSION OF THE BACKGROUND ART

There are spin stands that are used for testing at least one of the heads or disks that are the structural elements of hard disk drives (for instance, refer to FIG. 1 of JP (Kohyo) [National Publication of International Application, Unexamined] 2003-515,859; page 5 of JP (Kokai) [Unexamined Japanese Patent Publication] 2001-101,853, and page 4 of JP (Kokai) [Unexamined Japanese Patent Publication] 6[1994]-150,269).

The spin stand is the device that rotates the disk, or aligns the head with the disk that rotates. The preliminary structural components of the spin stand are a base, a disk-rotating means, and an alignment means. The disk-rotating means and the alignment means are fastened to the base. The alignment means comprise a stage for supporting a head, a drive means for driving the stage, and a position detection means for detecting the position of the stage. The stage is fastened to the base by a bearing.

The stage is disturbed by an outside force that is different from the force of the drive means. Today the alignment precision of a head on a spin stand must be 2 to 3 nanometers or less. Therefore, in order to maintain the required alignment precision, the position of the head is stabilized by anchoring the stage to the base once the stage has been moved to the desired position. A typical means for anchoring the stage to the base is an air chuck (for instance, refer to page 9 of JP (Kohyo) [National Publication of International Application, Unexamined] 2003-515,859 and page 5 of JP (Kokai) [Unexamined Japanese Patent Publication] 2001-101,853).

There are problems with the position stability of the stage after alignment when the base and the stage of a spin stand are coupled via a ball bearing or other antifriction bearing. First, a linear stage that is coupled with the base via a ball bearing is indirectly anchored to the base as a result of an air chuck fastened to the stage via a flat spring that is attached to the base. A flat spring will mainly deform in a specific direction, but will also deform, although slightly, in other directions. Therefore, the relative positional relationship between the air chuck and the stage is not stable. Moreover, there are no examples of using a rotating stage in a conventional spin stand; therefore, there is no prior art for anchoring a rotating stage to the base. In short, to date there are no means for anchoring a stage to a base with stability in a spin stand where the base and the stage are coupled via an antifriction bearing. However, the alignment precision required of spin stands increases each year. Moreover, there is also a demand for a spin stand that performs frequent, high-speed alignment.

Therefore, an object of the present invention is to provide a spin stand with which it is possible to accomplish a highly stable, high-speed anchoring of a stage fastened to a base via an antifriction bearing at the base.

### SUMMARY OF THE INVENTION

The present invention is a spin stand for testing a head or a disk that comprises a base and a stage fastened to the base via an antifriction bearing, characterized in that it further comprises an anchoring device, which is integrated as one unit with the base and the stage by being attached to the base and attached to the stage and thereby anchors the stage to the base, and with which it is possible to control the attachment as one unit of the base and the stage as well as the separation of the base and the stage.

The part of the anchoring device that couples the base and the stage by attachment is made from an solid unit. The phrase “solid unit” as used in this application is intended to refer to a deformable unit with no moving parts.

The spin stand also comprises a means for confirming the attached state of the anchoring device and the base or the attached state of the anchoring device and the stage.

The force that attaches the anchoring device and the base and the force that attaches the anchoring device and the stage are weaker once the anchoring device has been integrated with the base and the stage than before the base and the stage have been integrated.

The stage comprises a first magnetic body, the base comprises a the second magnetic body, and the anchoring device comprises a magnet for attaching to the first magnetic body and second magnetic body by magnetic force.

The spin stand further comprises a means for separating the magnet from the first magnetic body and the second magnetic body when the magnet is magnetically attached to the first and second magnetic bodies.

The base comprises two smooth surfaces, and the anchoring device comprises an air chuck that can be attached and removed from the first and second smooth surfaces by controlling air pressure.

By means of the present invention, an solid unit is attached to the base and stage; therefore, the base and stage are firmly integrated as one unit and the stage is anchored to the base. Moreover, pressure is not applied to the base and the stage and the load applied to the moving parts, such as the bearing parts related to the base and the stage is alleviated.

In addition, the state of attachment with the base and the stage can be confirmed by means of the present invention; therefore, the anchoring capability of the anchoring device can be realized with stability and certainty.

The present invention is such that the magnet in an attached state is pulled away under force; therefore, the anchored state of the stage can be released within a predetermined time.

By means of the present invention, the force of attachment of the anchoring device weakens once the anchoring device has been attached to both the stage and the base; therefore, the necessary electricity and generation of heat are controlled. Thus, for instance, it is possible to alleviate the effect of heat on the device under test and the equipment and circuits around the magnet.

### BRIEF DESCRIPTION OF THE DRAWINGS

FIG. 1 is an oblique view from the top showing a spin stand 100.

FIG. 2 is an oblique view from the bottom showing the spin stand 100.

FIG. 3 is a cross section of an anchoring device 300 of the present invention.

FIG. 4 is a cross section of the anchoring device 300 of the present invention.

FIG. 5 is a cross section of the anchoring device 300 of the present invention.

FIG. 6 is a cross section of an anchoring device 400 of the present invention.

FIG. 7 is a cross section of the anchoring device 400 of the present invention.

FIG. 8 is an oblique view from the top showing a spin stand 500.

FIG. 9 is a cross section of an anchoring device 700 of the present invention.

FIG. 10 is a cross section of the anchoring device 700 of the present invention

### DETAILED DESCRIPTION OF THE PREFERRED EMBODIMENT

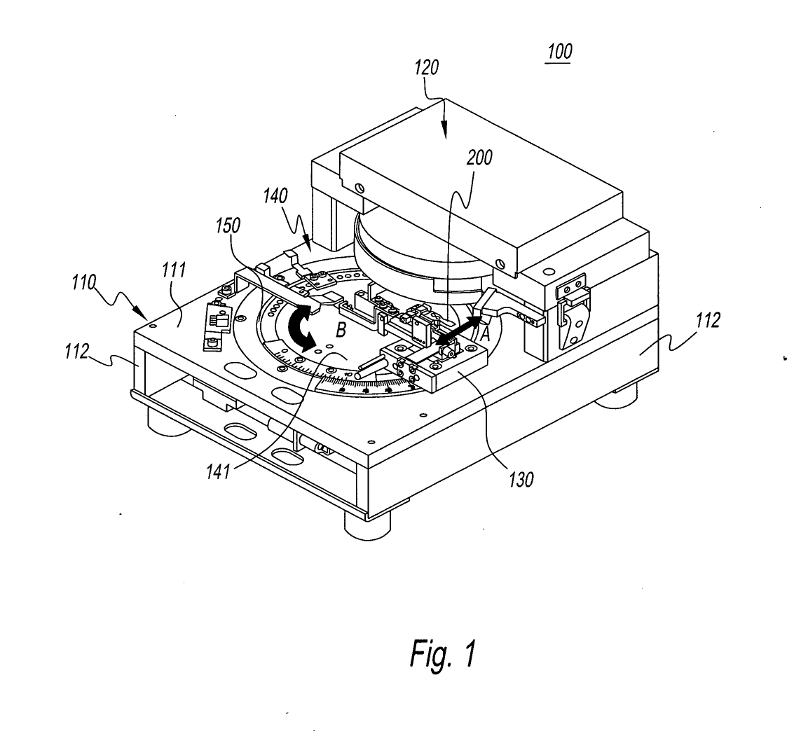

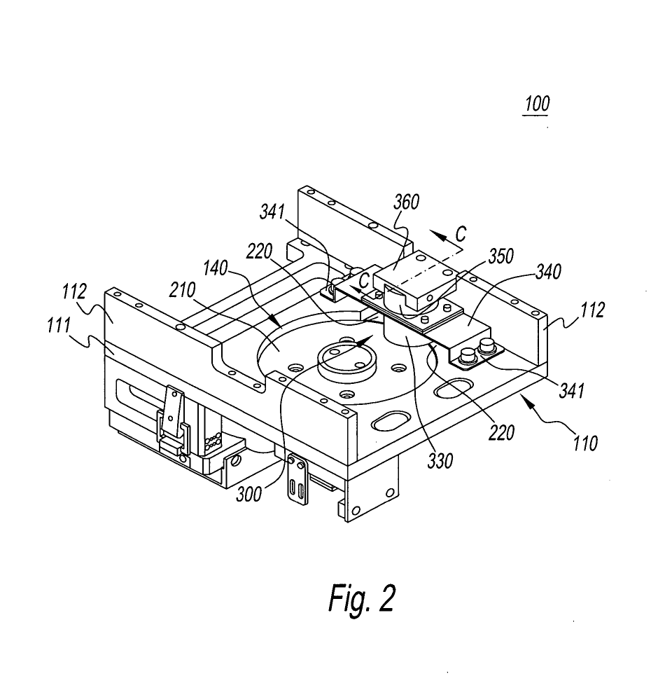

The present invention will now be described based on the preferred embodiments shown in the attached drawings. The first embodiment of the present invention is a spin stand 100 for testing at least one head or disk. Refer to FIGS. 1 and 2. FIG. 1 is a drawing wherein the spin stand 100 is shown at an inclined angle viewed from the top. FIG. 2 is a drawing wherein the spin stand 100 is shown at an inclined angle viewed from the bottom. The same reference numbers are used in FIG. 2 for the parts that are the same as in FIG. 1. Spin stand 100 comprises a base 110, a disk-rotating device 120, a piezo stage 130, and a rotating stage 140. Base 110 comprises a top plate 111 and side plates 112. Disk-rotating device 120 is the device that rotates disks, which are not illustrated. Piezo stage 130 is the device for linear fine alignment of a head 200, and is fastened on top of a top plate 141 of rotating stage 140. Piezo stage 130 aligns head 200 in the direction of arrow A. The direction of arrow A is the direction, or includes the direction, perpendicular to the gap center line (not illustrated) of head 200. Rotating stage 140 is fastened to base 110 via an antifriction bearing 150. Rotating stage 140 rotates and aligns piezo stage 130 in the direction of arrow B using a drive means and a position detecting means that are not illustrated. When piezo stage 130 is rotated and aligned, the alignment direction A of piezo stage 130 also changes.

Moreover, spin stand 100 comprises an anchoring device 300. Anchoring device 300 is the device that anchors rotating stage 140 to base 110 using a magnet 330. Magnet 330 is magnetically attached and integrated as one unit with base 110 and rotating stage 140; as a result, rotating stage 140 is anchored to base 110. Base 110 comprises a magnetic plate 220 for attaching magnet 330. Rotating stage 140 comprises a magnetic plate 210 for attaching magnet 330. Magnetic plates 210 and 220 are sheets made of iron.

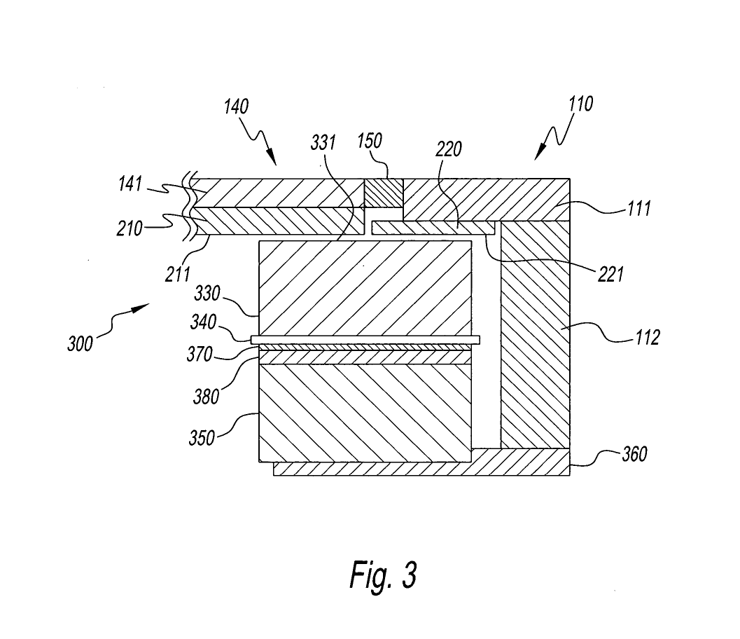

Refer to FIGS. 2 and 3 below. FIG. 3 is the C-C cross section of FIG. 2. The same reference numbers are used in FIG. 3 for the parts that are the same as in FIG. 2. There is no difference in grade between a surface 211 of magnetic plate 220 and a surface 221 of magnetic plate 220. Surfaces 211 and 221 are perpendicular to the rotating shaft of rotating stage 140. Magnet 330 is fastened to base 110 via a flat spring 340 such that an attachment surface 331 faces surfaces 211 and 222. Attachment surface 331 of magnet 330 is shaped such that it can simultaneously fit closely with surfaces 211 and 221. Flat spring 340 is bridge-shaped, and ends 341 thereof are anchored to base 110. Moreover, a magnetic plate 380 is attached to the surface of flat spring 340 at the surface opposite the surface to which magnet 330 is fastened. Magnetic plate 380 is a flat sheet made of iron. An insulator 370 is disposed in between magnetic plate 380 and flat spring 340. Insulator 370 is made from, for instance, MC Nylon®. A magnet 350 is fastened to base 110 via a support unit 360 such that it is opposite magnetic plate 380. A magnet 350 is not anchored to magnetic plate 380. The magnetism produced by magnets 330 and 350 is turned on and off and the magnetic force of the magnets is controlled by control circuit C, which is not illustrated. Control circuit C (not illustrated) can be a part of spin stand 100 or it can be an external device.

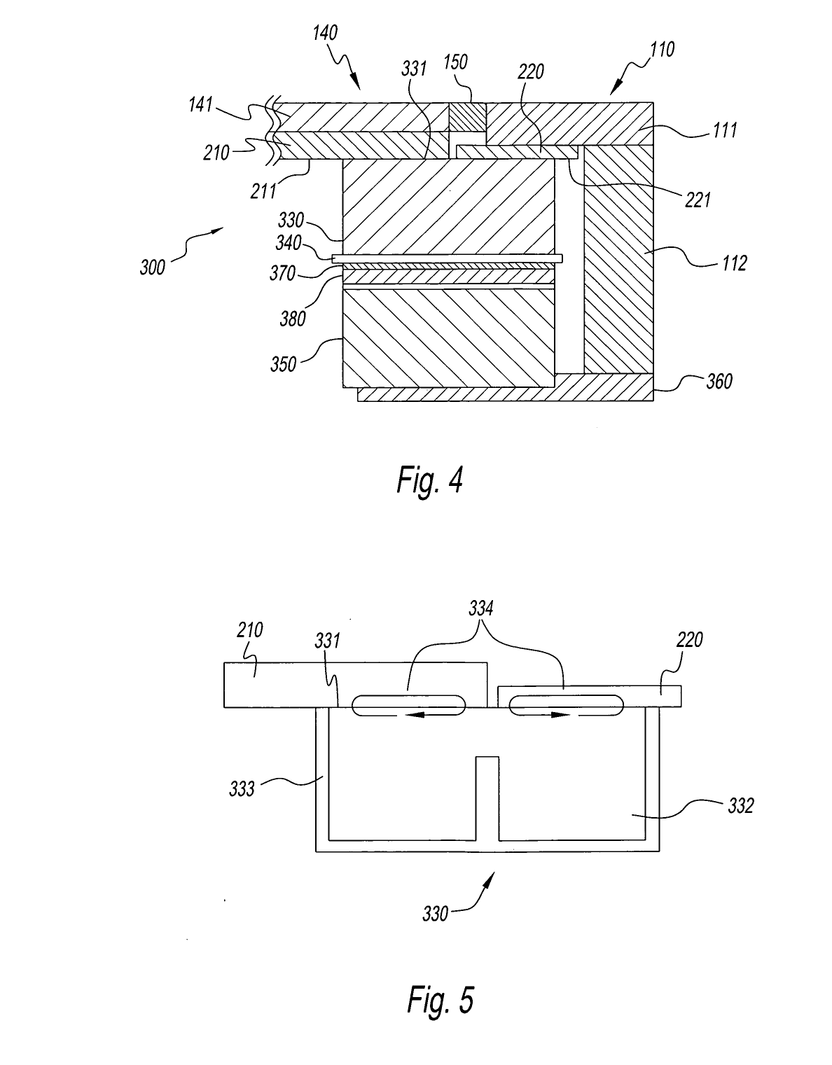

The operation of anchoring device 300 with the above-mentioned structure will now be described. FIG. 3 shows the state where rotating stage 140 and base 110 are not anchored. This is the normal state. When voltage is applied to magnet 330, magnet 330 is attached to magnetic plates 210 and 220 by the magnetic force that is generated. Refer now to FIG. 4. FIG. 4 is the same C-C cross section of FIG. 2 as in FIG. 3. However, it differs from FIG. 3 in that magnet 330 is attached to magnetic plates 210 and 220. The same reference numbers are used for the parts in FIG. 4 that are the same as in FIG. 3. Magnetic plate 210 in FIG. 4 is anchored so that it is integrated as one unit with magnetic plate 220 via magnet 330. Magnetic plate 210 is anchored to rotating stage 140 and magnetic plate 220 is anchored to base 110. Therefore, rotating stage 140 is anchored such that it is integrated as one unit with base 110 via magnet 330. Magnet 330 that couples rotating stage 140 and base 110 is a single solid unit; therefore, is integrated under force with rotating stage 140 and base 110 to obtain a stable anchored state. Moreover, magnet 330 is attached to magnetic plates 210 and 220; as a result, force is not applied to rotating stage 140 or base 110 when the anchored state is produced. Consequently, little load is applied to the rotating shaft of rotating stage 140 (not illustrated) or antifriction bearing 150.

As previously mentioned, attachment surface 331 of magnet 330 has a shape that simultaneously fits closely with surfaces 211 and 221. Thus, base 110 and rotating stage 140 are integrated into one unit under force. Nevertheless, if any dust or similar contamination penetrates in between surface 211 or 221 and attachment surface 331, the contact between the surfaces will not be complete; as a result, the anchored state between rotating stage 140 and base 110 will be unstable. Moreover, if magnet 330 is not carefully controlled, the anchored state between rotating stage 140 and base 110 will also be unstable. When head 200 is aligned with piezo stage 130 in this unstable anchored state, there is a chance that rotating stage 140 will move in the direction opposite to that in which head 200 is driven, and a high-precision alignment of rotating stage 140 and head 200 will not be achieved. Therefore, anchoring device 300 of the present embodiment applies voltage to flat spring 340 and confirms the state of contact between surface 221 and attachment surface 331 by confirming the conducting state between flat spring 340 and magnetic plate 220. Thus, it is possible to confirm the state of attachment of magnetic plate 210 and magnet 330 and also the state of attachment of magnetic plate 220 and magnet 330; therefore, the anchoring capability of the anchoring device can be realized with stability. In order to confirm the conducting state, magnet 330 and magnetic plate 220 are conductive. It is also possible to apply voltage to magnetic plate 210 and confirm that electricity is being conducted between magnetic plates 210 and 220. However, attachment surface 331 has a shape such that it can simultaneously contact surfaces 211 and 221; therefore, it is difficult for attachment surface 331 to touch only one of surfaces 211 and 221. Consequently, it is sufficient to confirm the state of contact between surface 211 or surface 221 and attachment surface 331 as described above.

FIG. 5 shows the path of the lines of magnetic force generated by magnet 330. Magnet 330 in the figure comprises a coil 332 and a core 333. The magnetic force of magnet 330 is produced by coil 332. When current flows to coil 332, there is an S pole near the center of coil 332 and an N pole near the outside periphery. Core 333 covers all of magnet 330, with the exception of the surfaces of magnet 330 that face magnetic plate 210 and magnetic plate 220. When magnet 330 is attached to magnetic plates 210 and 220, the magnetic line that is generated by coil 332 forms closed loops of magnetic flux 334 via magnetic plates 210 and 220. Moreover, the lines of magnetic force generated by coil 332 form a closed loop of magnetic flux with core 333. Virtually all of attachment surface 331 of magnet 330 can be covered. Consequently, when magnet 330 is attached to magnetic plates 210 and 220, the lines of magnetic force generated by coil 332 do not leak to the outside. In addition, attachment surface 331 of magnet 330 is disposed close to magnetic plates 210 and 220; therefore, virtually none of the lines of magnetic force generated by coil 332 will leak to the outside, even before magnet 330 is attached to magnetic plates 210 and 220. This is very important to devices for testing heads 200 and other magnetic elements. This is because effects from the surrounding magnetic field can influence the test results and are alleviated in this manner.

Moreover, magnet 330 generates a strong magnetic force until it becomes attached to magnetic plates 210 and 220, and once it is attached, the magnetic force that is generated weakens. For instance, just before magnet 330 is to be attached, 20 V are applied to magnet 330 and after attachment, the applied voltage is lowered to 10 V. This is because the magnetic force that is required to maintain an attached state once magnet 330 has attached to magnetic plates 210 and 220 can be reduced in comparison to the force when the magnet is to be attached. The amount of heat generated by magnet 330 can be reduced by controlling the applied voltage in this way.

Next, the operation for releasing the attached state of magnet 330 will be explained, that is, the state of attachment between magnet 330 and magnetic plate 210 and the state of attachment between magnet 330 and magnetic plate 220. The voltage applied to magnet 330 is first brought to zero in FIG. 4. Bringing the voltage applied to magnet 330 to zero does not mean that there is no closed loop of magnetic flux 334; therefore, magnet 330 is kept in an attached state. Moreover, when a voltage opposite to that applied for attachment is applied to magnet 330, the direction of the closed loop of magnetic flux 334 in FIG. 5 simply reverses itself. That is, the attached state of magnet 330 is maintained. Therefore, it is necessary to pull magnet 330 away from magnetic plates 210 and 220 under force in order to quickly release the attached state of magnet 330. Specifically, magnetic plate 380 is drawn in by magnet 350 and magnet 330 is thus pulled away from magnetic plates 210 and 220. As a result, anchoring device 300 is in the state shown in FIG. 3. Moreover, although not illustrated, like magnet 330, magnet 350 comprises a core and coil. In contrast to magnet 330, magnet 350 generates a strong magnetic force until it becomes attached to magnetic plate 380, but the magnetic force that is generated becomes zero once the magnet is attached. Once magnet 330 is pulled away from magnetic plates 210 and 220, anchoring device 300 comes to rest with flat spring 340 in the state shown in FIG. 3; therefore, it is not necessary for magnet 350 to continuously generate magnetic force. Magnetic plate 380 has a sufficient surface area for attachment and magnet 350 is disposed next to magnetic plate 380. Therefore, the lines of magnetic force that leak from magnet 350 can be controlled. This method with magnet 350, for instance, makes it possible to pull magnet 330 away within a specific time and with certainty when compared to methods where the magnet is pulled away under gravity by attaching a weight to magnet 330. Therefore, stable, high-speed release of the attached state of magnet 330 is possible.

Magnets 330 and 350 generate a magnetic field. There are times when this field can be a source of errors when measuring head 200 or another magnetic element. Magnetic plate 210 and similar components are disposed in spin stand 100 between head 200 and magnets 330 and 350; therefore, the magnetic field is kept from affecting the measurements of head 200.

There can be a difference in grades between surfaces 211 and 221 in the first embodiment, and attachment surface 331 can be graded to match this difference in grade. Moreover, surfaces 211 and 221 and attachment surface 331 can be curved rather than flat. In other words, the shape thereof does not matter as long as simultaneous attachment is possible.

Next, a second embodiment of the present invention will be described. The second embodiment of the present invention is a spin stand for testing heads or disks, and is the same as that shown in FIGS. 1 and 2. However, by means of the second embodiment of the present invention, an anchoring device 400 is used in place of anchoring device 300 in spin stand 100. Moreover, this results in several elements being omitted or modified. Anchoring device 400 is characterized in that an air chuck is used in place of the magnet as an attachment means.

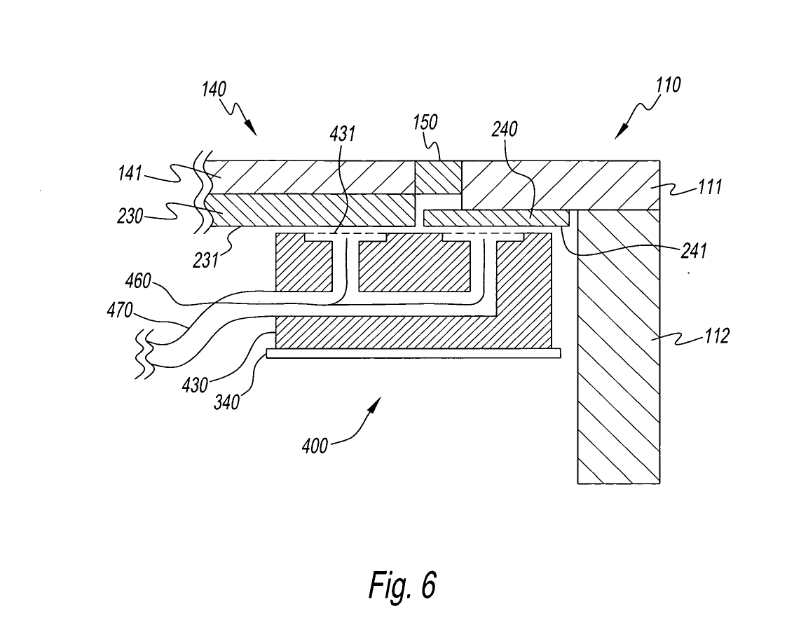

FIG. 6 shows a cross section of anchoring device 400 here. The same reference numbers are used for the elements in FIG. 6 that are the same as in FIGS. 2 and 3. Anchoring device 400 is a device for anchoring rotating stage 140 to base 110 using an attachment block 430. Attachment block 430 is fastened and integrated as one unit with rotating stage 140 and base 110 and this results in rotating stage 140 being anchored to base 110. Rotating stage 140 comprises a smooth plate 230 for attaching to attachment block 430. Base 110 comprises a smooth plate 240 for attaching to attachment block 430. Smooth plates 230 and 240 are sheets made from aluminum. Smooth plates 230 and 240 respectively comprise smooth surfaces 231 and 241 having a degree of roughness of 5 microns or less. Smooth surfaces 231 and 241 do not differ in grade. Moreover, smooth surfaces 231 and 241 are surfaces that are perpendicular to the rotating shaft of rotating stage 140.

Attachment block 430 comprises an air chuck 460 and an attachment surface 431. Attachment block 430 is fastened to base 110 via flat spring 340 such that attachment surface 431 faces smooth surfaces 231 and 241. Attachment surface 431 of attachment block 430 has a shape such that it can simultaneously attach to smooth surfaces 231 and 241. Flat spring 340 is bridge-shaped, and ends 341 thereof are anchored to base 110. The air pressure produced by air chuck 460 is turned on and off and the extent of this air pressure is controlled by an air feed-emission device P (not illustrated) connected to air chuck 460 via an air path 470. Air feed-emission device P (not illustrated) can be part of spin stand 100, or it can be an external device.

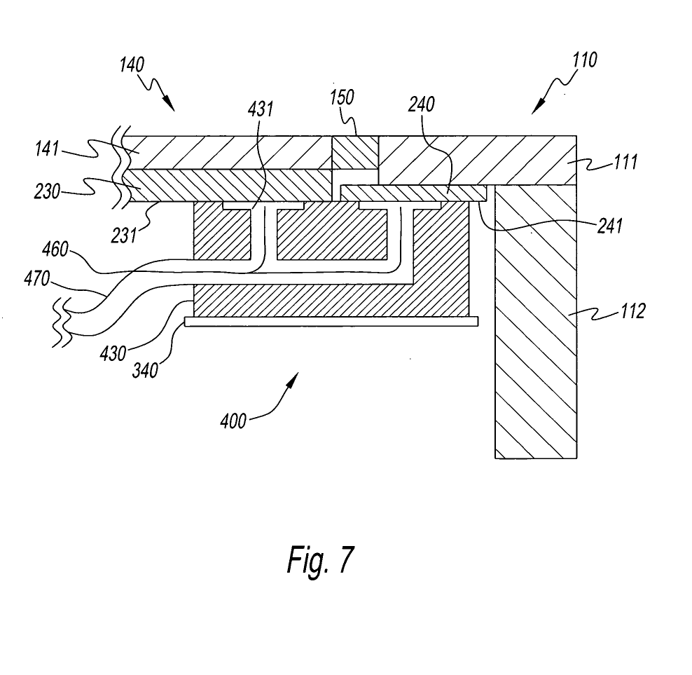

The operation of anchoring device 400 with the above-mentioned structure will now be described. FIG. 6 shows the state where rotating stage 140 and base 110 are not anchored. This is the normal state. Air is sucked into air chuck 460 by the effect of air feed-emission device P (not illustrated). When this is done, a negative pressure is generated at air chuck 460. Attachment block 430 attaches to smooth plates 230 and 240 under this negative pressure that is generated. Refer now to FIG. 7. FIG. 7 is a cross section showing the same anchoring device as in FIG. 6, but in contrast to FIG. 6, attachment block 430 is attached to smooth plates 230 and 240. The same reference numbers are used for the parts in FIG. 7 that are the same as in FIG. 6. Smooth plate 230 in FIG. 7 is anchored such that it is integrated as one unit with smooth plate 240 via attachment block 430. Smooth plate 230 is anchored to rotating stage 140 and smooth plate 240 is anchored to base 110; therefore, rotating stage 140 is anchored such that it is integrated as one unit with base 110 via attachment block 430. Attachment block 430 that couples rotating stage 140 and base 110 is a single solid unit, and a stable integrated state is obtained by integrating rotating stage 140 and base 110 as one unit under force. Moreover, attachment block 430 is attached to rotating stage 140 and base 110; therefore, force is not applied to rotating stage 140 or base 110 as a result of anchoring. Consequently, little load is applied to the rotating shaft (not illustrated) of rotating stage 140 or antifriction bearing 150.

As previously mentioned, attachment surface 431 of attachment block 430 has a shape that simultaneously fits closely with surfaces 231 and 241. Thus, base 110 and rotating stage 140 are integrated into one unit under force. Nevertheless, if any dust or similar contamination penetrates in between surface 231 or 241 and attachment surface 431, the contact between the surfaces will not be complete; as a result, the anchored state between rotating stage 140 and base 110 will be unstable. Moreover, if air chuck 460 is not carefully controlled, the anchored state between rotating stage 140 and base 110 will also be unstable. When head 200 is aligned with piezo stage 130 in this unstable anchored state, there is a chance that rotating stage 140 will move in the direction opposite to that in which head 200 is driven, and a high-precision alignment of rotating stage 140 and head 200 will not be achieved. Therefore, anchoring device 400 of the present embodiment confirms the state of contact between smooth surface 231 and attachment surface 431 as well as the state of contact between smooth surface 241 and attachment surface 431 by confirming the load applied to air feed-emission device P (not illustrated). The difference between the load applied to air feed-emission device P (not illustrated) when contact between these surfaces is complete and when it is incomplete is used. As a result, it is possible to provide a stable anchoring capability of anchoring device 400.

Attachment block 430 generates a strong negative pressure until it becomes attached to smooth plates 230 and 240, and once it does become attached, this negative pressure is greatly diminished. This is because once attachment block 430 has become attached to smooth plates 230 and 240, the negative pressure needed to maintain the attached state can be smaller than before the block becomes attached. Of course, it is not necessary to reduce the negative force that is generated after attachment.

Next, the operation for the release of the attached state of attachment block 430, that is the attached state of smooth plate 230 and attachment block 430 and the attached state of smooth plate 240 and attachment block 430, will be described. Air is released from air chuck 460 by the operation of air feed-emission device P (not illustrated). As a result, a positive pressure is generated at air chuck 460. Attachment block 430 is pulled away from smooth plates 230 and 240 by the positive pressure that is generated. Anchoring device 400 wherein the attached state of attachment block 430 has been released is as shown in FIG. 6. Once attachment block 430 moves away from smooth plates 230 and 240, anchoring device 400 comes to rest as shown in FIG. 6 and there is no need for air chuck 460 to continuously generate a positive pressure. Just as when a magnet is used, it is possible to pull attachment block 430 away within a specific time and with certainty by the release method with air chuck 460; therefore, a stable, high-speed release of the attached state of attachment block 430 is possible. Moreover, when compared to the use of a magnet, the method that uses air chuck 460 does not require an additional means for releasing the attached state of attachment block 430. In addition, the method that uses air chuck 460 has virtually no effect on the head test results.

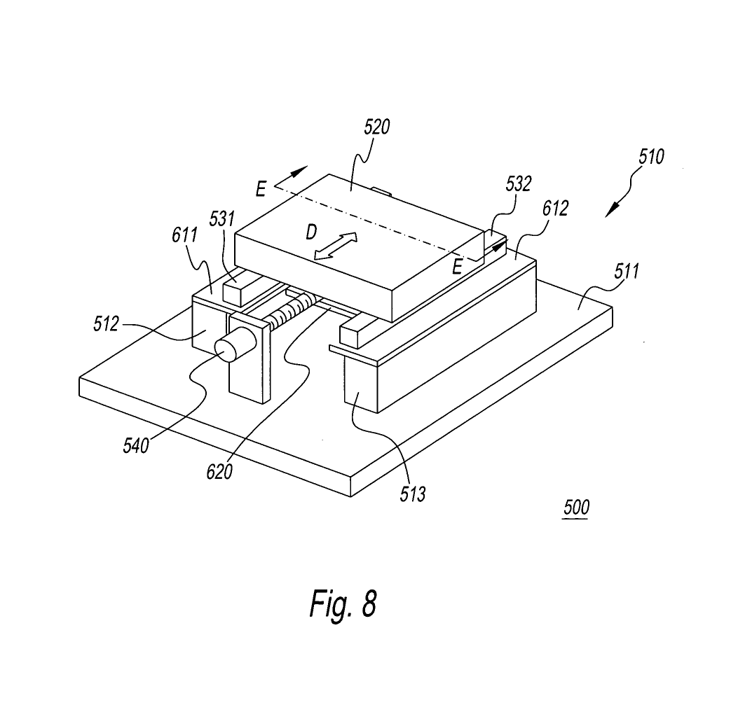

A third embodiment of the present invention will now be described. The third embodiment of the present invention is a spin stand 500 for testing at least one head or disk. Refer now to FIG. 8. FIG. 8 is a drawing showing spin stand 500 at an inclined angle viewed from the top.

Spin stand 500 comprises abase 510 and a linear stage 520. Base 510 comprises a top plate 511 and support poles 512 and 513 standing upright on top plate 511. Support pole 512 comprises a magnetic plate 611 at the top. Support pole 513 comprises a magnetic plate 612 at the top. A linear guide 531, which is one example of an antifriction bearing, is fastened to the top of magnetic panel 611. A linear guide 532, which is an example of an antifriction bearing, is fastened to the top of magnetic plate 612. Linear stage 520 is supported by linear guides 531 and 532, and is aligned in the direction of arrow D by a drive source 540. Moreover, linear stage 520 comprises a magnetic plate 620 at the bottom.

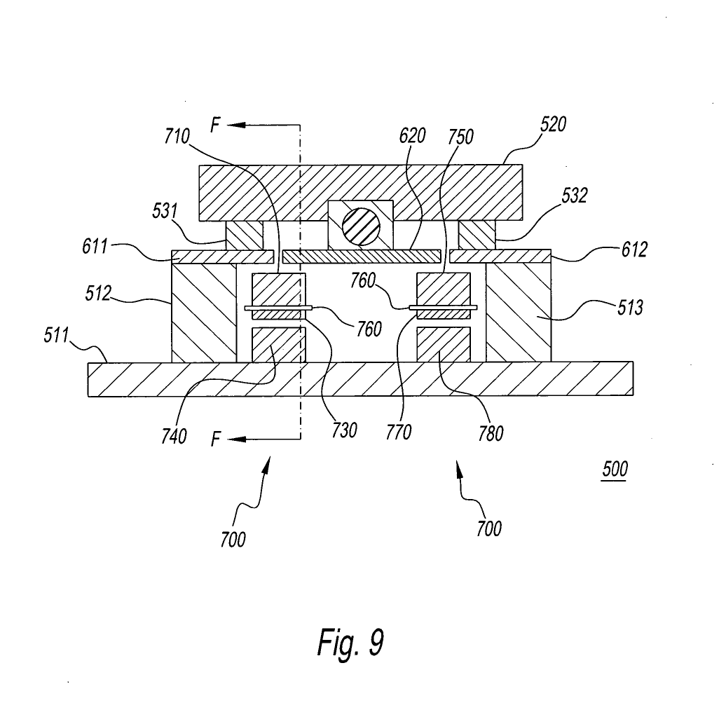

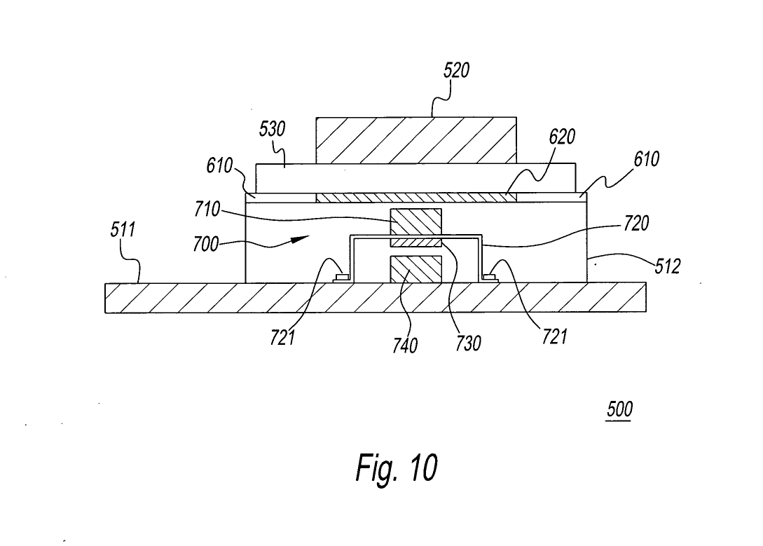

Refer to FIGS. 9 and 10 next; FIG. 9 is the E-E cross section in FIG. 8. FIG. 10 is the F-F cross section in FIG. 9. The same reference numbers are used for the parts in FIG. 9 that are the same as in FIG. 8. The same reference numbers are used for the parts in FIG. 10 that are the same as in FIG. 9. Spin stand 500 comprises an anchoring device 700. Anchoring device 700 is the device that anchors linear stage 520 to base 510 using magnets 710 and 750. Magnet 710 is attached to and is integrated as one unit with magnetic plates 611 and 620, and magnet 750 is attached to and is integrated as one unit with magnetic plates 612 and 620. Anchoring device 700 anchors rotating stage 140 to base 110 by this integration of parts.

Magnet 710 is attached to base 510 via a flat spring 720. Magnet 750 is attached to base 510 via a flat spring 760. Magnet 710 has a shape such that it can simultaneously fasten to magnetic plates 611 and 620. Magnet 750 has a shape such that it can simultaneously fasten to magnetic plates 612 and 620. Flat spring 720 is bridge-shaped, and ends 721 thereof are anchored to base 510. Magnetic plate 730 is fastened to the surface of flat spring 720 opposite the surface to which magnet 710 is attached. Magnetic plates 730 and 770 are sheets made of iron. Magnetic plate 730 and flat spring 720 are electrically insulated. Magnetic plate 770 and flat spring 760 are also electrically insulated. A magnet 740 is fastened to base 510 such that it faces magnetic plate 730. Moreover, a magnet 780 is fastened to base 510 such that it faces magnetic plate 770. The magnetic forces generated by magnets 710, 740, 750, and 780 are turned on and off and the extent of these forces is controlled by a control circuit G that is not illustrated. Control circuit G (not illustrated) can be a part of spin stand 500 or it can be an external device.

The operation of anchoring device 700 made as described above will now be explained. FIGS. 9 and 10 show free-acting stage 520 and base 510 in an unanchored state. This is the normal state. When voltage is applied to magnets 710 and 750, magnet 710 becomes magnetically attached to magnetic plates 611 and 620, and magnet 750 becomes magnetically attached to magnetic plates 612 and 620. Magnet 710 and magnetic plates 611, 612, and 620 are conductive. Therefore, as in the first embodiment, the state of attachment between magnet 710 and magnetic plates 611 and 620, and the state of attachment between magnet 750 and magnetic plates 612 and 620 can be electrically confirmed. Magnetic plate 620 is anchored to free-acting stage 520, and magnetic plates 611 and 612 are anchored to base 510. Therefore, free-acting stage 520 is anchored, integrated as one unit with base 510 via magnets 710 and 750. Magnets 710 and 750 that couple linear stage 520 and base 510 are a single solid unit, so that linear stage 520 and base 510 therefore are integrated as one unit under force to obtain a stable state. Moreover, pressure is not applied to linear stage 520 or base 510 when they are anchored. Magnets 710 and 750 generate strong magnetic forces until they become attached to magnetic plates 620, etc., and after they become attached, the magnetic force that is generated weakens. When the state of attachment of magnets 710 and 750 is released, the voltage applied to magnets 710 and 750 becomes zero, and magnets 710 and 750 are pulled away from magnetic plates 620, etc., under force by magnets 740 and 780.

The magnetic plates in the first and third embodiments should be magnetic bodies such that magnets can be attached. Therefore, they are not limited to iron and can also be made of nickel, cobalt, and similar materials.

In addition, the smooth plates in the second embodiment should have a smooth surface such that the attachment blocks can attach. Therefore, they are not limited to aluminum and can be made of iron, or another metal, resin, and similar materials.

The means used to confirm the state of attachment in the first through third embodiments is not limited to electrical means, and optical or mechanical means can also be used.

Furthermore, the shape of the attaching part in the first through third embodiments is not necessarily flat.

The insulation in the first through third embodiments must be a material that provides an electrical insulation; therefore, it can be made from ceramic, rubber, and similar materials.

The anchoring device in the first through third embodiments can use an attachment means other than a magnetic force or a negative pressure.

What is claimed is:

1. A spin stand for testing a head or a disk that comprises a base and a stage fastened to the base via an antifriction bearing, wherein said spin stand further comprises an anchoring device, which is integrated as one unit with the base and the stage by being attached to the base and attached to the stage and thereby anchors the stage to the base, and with which it is possible to control the attachment as one unit of the base and the stage as well as the separation of the base and the stage.

2. The spin stand according to claim 1, where the part of the anchoring device that couples the base and the stage by attachment is made from an solid unit.

3. The spin stand according to claim 1, further comprising a detector for confirming the attached state of the anchoring device and the base or the attached state of the anchoring device and the stage.

4. The spin stand according to claim 1, wherein the force that attaches the anchoring device and the base and the force that attaches the anchoring device and the stage are weaker once the anchoring device has been integrated with the base and the stage than before the base and the stage are integrated.

5. The spin stand according to claim 1, wherein the stage comprises a first magnetic body, the base comprises a second magnetic body, and the anchoring device comprises a magnet for attaching to the first magnetic body and the second magnetic body by magnetic force.

6. The spin stand according to claim 5, further comprising a magnet for separating the magnet from the first magnetic body and the second magnetic body when the magnet is magnetically attached to the first and second magnetic bodies.

7. The spin stand according to claim 1, wherein said base comprises two smooth surfaces, and said anchoring device comprises an air chuck that can be attached and removed from the first and second smooth surfaces by controlling air pressure.
